(19) United States
(12) Patent Application Publication
(10) Pub. No.: US 2012/0120622 A1
(43) Pub. Date: May 17, 2012

(54) AIRTIGHT ASSEMBLY OF TWO COMPONENTS AND METHOD FOR PRODUCING SUCH AN ASSEMBLY

(75) Inventors: François Marion, Saint Martin Le Vinoux (FR); Agnés Arnaud, St. Jean Le Vieux (FR); Geoffroy Dumont, Grenoble (FR); Pierre Imperinetti, Seyssins (FR)

(73) Assignee: Commissariat L'Energie Atomique Et Aux Energies Alternatives, Paris (FR)

(21) Appl. No.: 13/384,539

(22) PCT Filed: Jul. 23, 2010
(86) PCT No.: PCT/FR2010/051561

§ 371 Date: Jan. 17, 2012

(30) Foreign Application Priority Data
Aug. 13, 2009 (FR) 0955658

(51) Int. Cl. H05K 5/06; H05K 13/00

(52) U.S. Cl. 361/758; 29/428

(57) ABSTRACT

An airtight assembly of two components including a first component with a support having at its surface: at least one spacer composed of a ductile material, arranged at the periphery of the component, and at least one bead composed of a ductile material; a second component with a support having at its surface: at least one insert inserted over the whole or part of its surface in the spacer on the first component, and at least one bead insert inserted over all or part of the surface thereof in the bead on the first component, defining an airtight central cavity.

### CROSS-REFERENCE TO RELATED APPLICATIONS

The present application is a National Stage Application of PCT International Application No. PCT/FR2010/051561 (filed on Jul. 23, 2010), under 35 U.S.C. §371, which claims priority to French Patent Application No. 0955658 (filed on Aug. 13, 2009), which are each hereby incorporated by reference in their respective entireties.

### FIELD OF THE INVENTION

The technical field to which the invention relates is that of microelectronics. Embodiments of the present invention concerns, more particularly, devices requiring simultaneously the vertical connection (better known by the expression “flip-chip”) of two components and an airtight protection of the components of the SOC (the acronym for the expression “System on Chip”) type.

The present invention has a special advantage for devices that are not capable of withstanding high packaging temperatures, functioning in a special atmosphere or requiring thorough protection against external attacks, such as bolometric imagers bonded collectively under vacuum on a Complementary Metal Oxide Semiconductor (CMOS) wafer.

### BACKGROUND OF THE INVENTION

Chip-to-wafer (C2W) bonding of electronic components on a wafer is, for example, described in the IMAPS 2008 paper (Lecarpenier et al., Proceeding 4th conference on device packaging, Scottsdale Ariz., March 2008, DPO8-TA1-P06). This document describes the combination of the chip-to-wafer technique with a fluxless soldering technique, under controlled atmosphere, in order to provide an airtight assembly.

This publication, therefore, demonstrates the implementation of a method also described in the document FR 2 780 200. In general terms, the latter proposes to encapsulate a component arranged on a support by means of a lid, by virtue of a sealing means surrounding the component and at least one spacer of fusible material with an initial height greater than that of the sealing means, so as to position the lid correctly before fusion.

It turns out that, in all the techniques of bonding on wafer proposed in the prior art, a heating step is in general necessary during assembly: it ensures the assembly of the protective lid on the components to be protected, by virtue of a sealing bead produced in the form for example of a metal weld, a laser weld or a glass weld. However, said components cannot tolerate such thermal stresses.

Moreover, the techniques proposed require the application of a force during the airtight sealing. H-lowever, some components cannot tolerate such mechanical stresses.

In the field of vertical connections strictly speaking, it has been proposed, in particular in the document WO 2006/054005, to effect a simultaneously electrical and mechanical connection between two components, using techniques of inserting a hard material in a soft material at low temperature and with a low force.

There exists an obvious need to develop novel technical solutions for assembling two components and simultaneously providing the functions of vertical connection and airtightness, without the aforementioned drawbacks of the prior art.

### SUMMARY OF THE INVENTION

Embodiments of the present invention are related to components designed to enable airtight vertical assembly. In accordance with a first aspect, the invention therefore concerns such an airtight assembly, illustrated in the drawing figures.

Such an assembly is characterised by the presence of at least two components to be connected vertically, of the chip-to-wafer (C2W) or wafer-to-wafer (W2W) type.

The present application, therefore, finds numerous applications, in particular concerning: (i.) C2W or W2W lidding for all types of application: bolometers, MEMS, gas detectors, hermetic optics, biochips, cooled infrared, etc; and (ii.) bolometric detection matrices with a transparent lid or provided with near-field optics (gratings, filters, etc). Since the invention makes it possible to align the lid and the detection matrix to better then +/−1 μm, it is possible to produce layers on the top or bottom face of the lid.

By way of favoured example, it may, therefore, be a case of an assembly between a lid, advantageously having filters at the central cavity, and a bolometer, advantageously having studs at the central cavity.

More precisely, the first component of the assembly includes a support having at the surface thereof: at least one spacer consisting of a ductile material, arranged at the periphery; and at least one bead consisting of a ductile material, defining a cavity or a space.

In a complementary fashion, the second component includes a support having at the surface thereof: at least one insert, inserted over all or part of the surface thereof in the spacer; and at least one bead insert, inserted over all or part of the surface thereof in the bead, thus defining an airtight central cavity.

The spacer or spacers, advantageously in the form of balls, is or are therefore advantageously produced from a ductile or soft material, advantageously a metal (for example, copper, aluminium, indium, solder material and/or tin-based compounds), in which an insert produced from a material having greater hardness can be inserted.

These spacers are advantageously placed at the periphery of the support, preferentially symmetrically. This arrangement has the advantage of conferring greater stability on the assembly, in particular, as will be detailed below, during the pre-insertion step.

The presence of these spacers also releases a space between the sealing means, in this case the bead and the bead insert in order provide the pumping, in particular of gas, into the cavity that they are supposed to define.

Typically, these spacers are four in number, arranged at the four corners of the support.

The bead which makes a second soldering element, characteristic of the first component, is a means of sealing or hermetically closing the cavity. More particularly, it is an element in bead or ring form, hereinafter referred to as a bead. Since it is also intended to receive an insert, it is advantageously produced from a ductile or soft material, advantageously a metal (for example, copper, aluminium, indium, solder and/or tin-based compounds), having a hardness less than that of the insert. This material is optionally of the same nature as that which composes the spacers.

Advantageously, the spacers are spatially situated outside the bead. The bead, therefore, defines a central area that, in the assembly, constitutes an airtight central cavity, isolated from the outside and able to accept a component to be protected. Several concentric beads, in particular two, can be envisaged on the surface of this first component.

In accordance with another advantageous embodiment of the invention, the initial height of the spacers is greater than that of the bead. Thus, and as will be detailed below, these elements actually fulfil their role of a spacer in particular during the pre-insertion step: before insertion, the spacer prevents the sealing means (bead) from connecting the two supports whereas after insertion it allows airtight contact of the sealing means (bead) with the two supports.

Under certain conditions, these spacers undergo a mechanical deformation in the assembly and are therefore crushed or compressed. According to this configuration, the height of the insert of the second component is less than the height of the spacer of the first component. Thus, during the pre-insertion step, the force exerted on the second component and/or the surface of the second component in the vicinity of the insert will deform or compress the spacer until the said insert comes into abutment on the first component.

Importantly, and as already stated, these elements made from ductile material (spacers and beads) are arranged on the surface of the component and are therefore raised rather than buried or embedded. This confers thereon an ability to sag or to be crushed and to undergo plastic deformation in a direction parallel to the surface of the component, during insertion, which can take place with a low force (almost zero).

The second component for its part is characterised by the presence of two sets of inserts situated on the surface of the support: a first set of inserts, referred to as pre-insertion or raising inserts, intended to be inserted in the spacers as defined above. The number, positioning and size thereof depend therefore on those of the spacers; and a second set of inserts, referred to as bead or ring inserts, intended to be inserted in the bead as defined above. The number, positioning, and size thereof depend therefore on those of the bead.

Advantageously, the two sets of inserts are produced from the same material, having a hardness greater than those of the spacer and bead. These are preferably produced using W, WN, WSi, Pt, Ti or TiW or may be dual layer, consisting of a layer of metal covered with a layer of gold.

In accordance with another favoured embodiment of the invention, the two sets of inserts have a similar or even identical height.

Moreover and preferentially, at least one of these inserts or even all of them are hollow. Hollow inserts have already been described, for example in the publication ECTC 2008 (Saint-Patrice et al., Proceedings Electronic and Components Technology Conference, Orlando, 2008, pp 46-53). They may have an annular cross section, in particular round or oval, or parallelepipedal, advantageously square or rectangular. Typically these inserts are in the form of tubes with a height and diameter of a few micrometers (for example 3 to 10 μm) and a thickness of a few hundreds of nanometers (for example 150 nm).

The insertion thereof in the spacer and/or bead, respectively, can be done in accordance with two embodiments.

In accordance with a first embodiment, the insert is inserted over the entire surface thereof. In this case, it is necessary to provide an insert diameter or width compatible with (namely less than) the dimensions of the spacers and beads. Preferentially, in the case of hollow inserts, these have a bevelled free end so that, at the time of insertion, no gas is trapped. During pre-insertion, the height of the bevel is greater than the height of what is pre-inserted.

Alternatively, the insertion can be done solely over part of the surface of the insert. The latter is therefore situated in a position offset with respect to the spacer or bead and therefore overlapping in the assembly. As illustrated in the drawing figures, even in the case of hollow inserts, there is no trapping of the atmosphere in the pre-insertion and/or insertion step, and therefore, no trapping of bubbles. It is therefore a case of designing and positioning the inserts so as to be offset with respect to the spacers and/or bead.

In order to guarantee a better seal, it is possible to provide several bead inserts, to be inserted either in the same bead or in several beads.

It is possible to envisage arranging several components of one type on the same component of the other type, having the insertion or soldering elements the number of times necessary. In this regard, the drawing figures illustrate several components (B) provided with inserts assembled with a component (A) having a succession of soldering elements.

In accordance with a particular embodiment, it is also possible to produce a vertical stack of these assemblies. This particular embodiment, referred to as “batch,” makes it possible to stack several wafers under vacuum. It may be advantageous to make provision for interposing, between each assembly, a layer of a flexible material so as to compensate for the variability in height of the assemblies.

In accordance with another aspect, the invention concerns a method of manufacturing an assembly or stack as just described. Such a method, illustrated also in the drawing figures, includes the following steps: putting surfaces of the components including the spacer and the bead on the one hand and the inserts on the other hand opposite each other; partially or totally aligning the spacer and insert, and also the bead and the bead insert; pre-inserting at least the pre-insertion insert in the spacer; and then inserting the inserts in the spacer and bead.

Notably, all the steps of this method can be performed at ambient temperature, advantageously less than or equal to 30° C. Thus, a temperature rise is not necessary.

It should be noted that, as illustrated in the drawing figures, the pre-insertion step may result in two distinct situations, having implications in the following insertion step.

In a first case, the raising insert is already completely inserted, and therefore, in abutment in the spacer, before the bead insert contacts the solder bead. To compensate for the force exerted by the spacer, it is necessary to deform this element mechanically. This makes it possible: (i.) to insert the bead insert in the bead, despite the force exerted by the raising element on the flat part of the component B; and then (ii.) to insert the bead completely.

In this case, it is necessary to size the spacers so that the deformation thereof does not require forces greater than the forces required by the insertion of the bead. The pre-insertion step, therefore, results only in the insertion of the insert in the spacer and the insertion step results in the deformation of the spacer.

In the second case, the raising insert is not completely inserted in the spacer, before the bead insert contacts the solder bead. In this case, the pre-insertion step results in the insertion of the two sets of inserts in the spacer and in the bead, respectively, and the insertion step does not deform the spacer.

In the final device, it is therefore clear that the height of the spacers may be greater than or equal to that of the bead, advantageously greater in the second case.

The final insertion is performed under controlled atmosphere, advantageously at a pressure of less than 10⁻³ mbar. It may be collective, that is to say may concern several components arranged on the same component or several stacked assemblies. In the latter case, a layer produced from a flexible material is advantageously placed between the assemblies, before the insertion step.

In general terms, the forces to be exerted in the pre-insertion and insertion steps are relatively small, or even almost zero. Value ranges are difficult to define since they depend on various parameters such as: effective cross section and number of inserts (in particular for the pre-insertion force); cross section and number of beads, nature of the ductile material, number and form of the balls (in particular for the insertion force), etc.

As already stated, the device and method in accordance with the invention enable the collective insertion of pre-inserted wafers. The cost of the final insertion operation may prove to be high since it is a case of performing an operation under vacuum or under special controlled atmosphere conditions.

Thus, in accordance with a preferred implementation scheme illustrated in the drawing figures, the final insertion step is performed as follows: stacking several wafers (C2W or W2W) that have undergone the pre-insertion step and placement in a process chamber under a press; putting the chamber under a chosen controlled atmosphere (the inside of the cavity is accessibly by virtue of the controlled-height spacers); and then pressing the stack formed with global establishment of airtightness under all the cavities.

As illustrated in the drawing figures, in order to compensate for the differences in height of the pre-inserted chips, a layer of flexible material is advantageously introduced between each pre-inserted and stacked wafer. This layer, advantageously produced from a flexible material such as Teflon (polytetrafluoroethylene), an elastomer film, or any material able to absorb deformation under stress, makes it possible to absorb the differences in height relating to the pre-insertion process or to the variability in height of the transferred chips.

The advantages of an assembly in accordance with the invention and of the method enabling manufacture thereof are numerous. For instance, airtightness can be achieved with almost zero force and/or at ambient temperature.

Moreover, the method used makes it possible to achieve a collective airtightness very simply: in practice, a standard “pick and place” positioning machine pre-inserts M lids before soldering (the assemblies produced can then be moved without risk of misalignment “before final insertion”). A stack of N wafers including M pre-inserted components can be completely inserted in a chosen atmosphere. Then the soldering step proper is proceeded with, in two possible ways, either at ambient temperature or by raising the temperature. If heating is carried out to a temrrperature higher than the melting point of the spacer: there is soldering with the formation of a metallurgical connection. Also, if the work is done at ambient temperature, the metallurgical connection takes place by interdiffusion (indium insert for example, gold spacer).

The contact surface between the inserts is maximised compared with the soldering volume involved. It is, therefore, possible to recover the solder in a “solder reservoir” situated at the bottom of the female tube, namely the hollow inserts.

### BRIEF DESCRIPTION OF THE DRAWINGS

The way in which the invention may be implemented, together with the resulting advantages, will become clearer from the description of the following embodiments, supported by the appended drawings.

FIGS. 1A to 1B illustrate respectively a schematic view in plan and in cross section of an assembly in accordance with embodiments of the invention.

FIGS. 2A to 2C describes the various steps of a method of manufacturing an assembly in accordance with embodiments of the invention.

FIGS. 3A to 3B illustrate respectively a schematic concerning the assembly at the end of the pre-insertion step.

FIG. 4 illustrates schematically a stack of assemblies at the end of the pre-insertion step.

FIG. 5 illustrates the arrangement of a layer of flexible material for compensating for the variability in height of the assemblies, in particular of the components B, at the end of the pre-insertion step.

FIGS. 6A to 6B illustrate respectively the pre-insertion and insertion steps in the case of offset hollow inserts.

FIGS. 7A to 7B illustrate respectively a schematic plan view of a lid and a bolometer before assembly.

FIG. 8 illustrates a schematic view in cross section of a bolometer wafer having on its surface a pre-insertion insert and “bolometer” studs.

FIG. 9 illustrates a schematic view in cross section of a bolometer wafer having on its surface a double ring insert and “bolometer” studs.

FIGS. 10A to 10B illustrates respectively a schematic view in cross section of the assembly of the two components A and B at the end of the pre-insertion step and at the end of the insertion step.

### DETAILED DESCRIPTION OF EMBODIMENTS

Embodiments of the invention will be illustrated below by way of a particular application relating to the lidding of chips of the bolometer type using a functionalised lid. In this application, and as will be detailed below, a double-insert bead is used.

By way of dimensions of the characteristic elements of the invention, the following example can be given: distance between the bead 3 and the spacer 1 is 100 μm, width of bead 3 is 100 μm, width of the bead insert 4 is 80 μm, and any horizontal offset between the bead insert 4 and the bead 3 is 10 μm.

### Components Before Assembly

The example relates to bolometric detection matrices with transparent lid or provided with near-field optics (gratings, filters, etc).

The aim sought is to align the lid and the detection matrix to better than +/−1 μm and to produce filtering layers on the top or bottom surface of the lid, so as to obtain an infrared spatial spectrometer. Plan views of the components before assembly are illustrated in FIGS. 7A to 7B.

FIG. 7A illustrates the lid corresponding to the component A. This is provided with four support balls 1 serving as a spacer, and a solder bead 3 delimiting a central area 5 in which filters 7 are arranged.

FIG. 7B illustrates the bolometer corresponding to the component B. This is provided with four “pre-insertion” inserts 2, and two “bead” inserts 4. In the central area 5 “bolometer” studs 8 are arranged.

### 1-1 Manufacture of the Lids

The lids A are produced by way of a material transparent to infrared, of the silicon, germanium or ZnSe type. They are then provided with solder elements of the ball type 1 and of the bead type 3, the balls being situated outside the bead. These elements are produced for example by electrolysis and then remelting.

Typically, the balls 1 have a diameter of 45 μm and a height of 35 μm, whereas the beads 3 have a width of 100 μm and a height of 20 μm. The balls 1 are advantageously four in number, and are spatially situated at the four corners of the lid.

On the lid and on the same face, inside the central area 5 defined by the bead, band-pass infrared filters with different wavelengths 7 are arranged.

### 1-2 Manufacture of the Bolometer Wafers:

The bolometers are produced in a traditional manner, using studs supporting a bolometric strip, hereinafter referred to as “bolometer” studs 8, with a height of 3 urpm, as illustrated in FIG. 8.

Advantageously, the pre-insertion inserts 2 are produced using the same materials and using the same method steps as those used for the manufacture of the “bolometer” studs. These inserts 2 are treated so as to keep only the vertical part of the material of the stud, as described in the publication ECTC 2008 (Saint-Patrice et al., Proceedings Electronic and Components Technology Conference, Orlando, 2008, pp 46-53), so that it is a case of hollow cylindrical inserts.

They advantageously have a height of 3 μm and a diameter of 10 μm, enabling them to be inserted over the entire surface thereof in the balls 1. They are advantageously four in number arranged at the four corners of the surface of the wafer and opposite the four balls 1 of the lid.

As illustrated in FIG. 9, the double insertion ring 4 includes two hollow inserts in the form of concentric beads. It is produced using the same materials and using the same method steps as those used for manufacturing the “bolometer” studs. This double ring 4 is also treated in the same way as the pre-insertion inserts 2.

Such a ring 4 has, for example, two double inserts with a width of 10 μm, spaced apart by 10 μm, that is to say 30 μm in total, compatible with insertion thereof over the entire surface thereof in the bead 3. It advantageously has a height equivalent to that of the pre-insertion inserts 2 and of the “bolometer” studs 8, that is to say 3 μm. It is positioned on the wafer of the bolometer so as to be opposite the bead 3 of the lid.

### Assembly

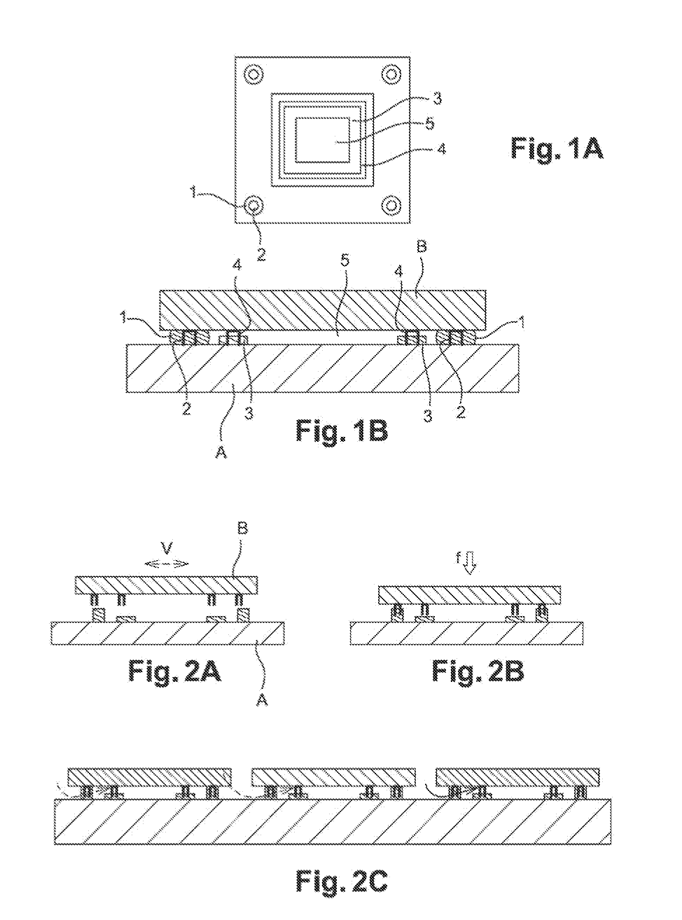

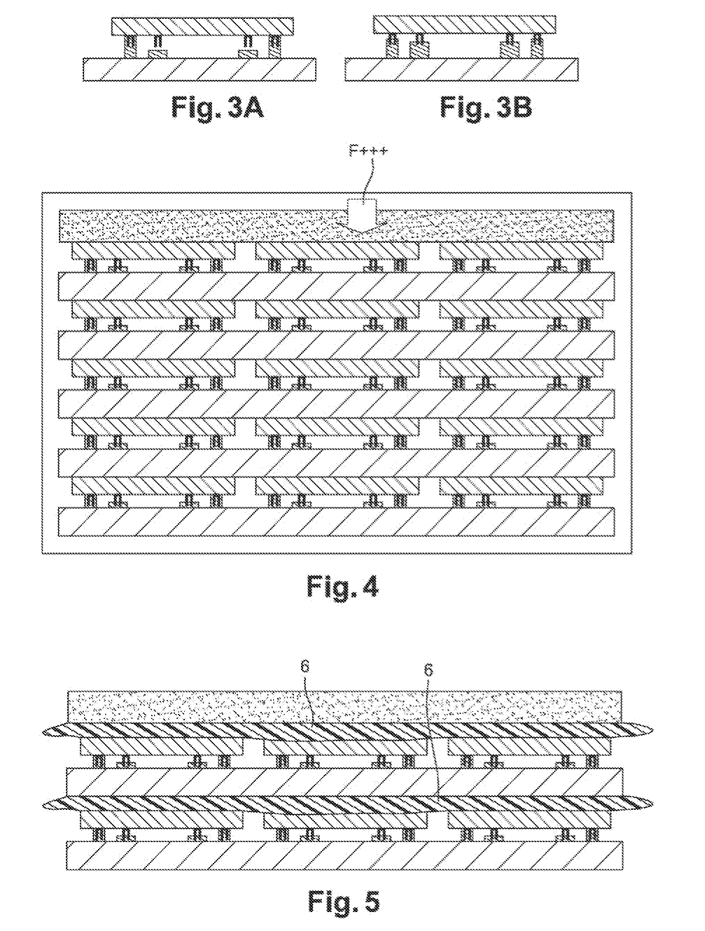

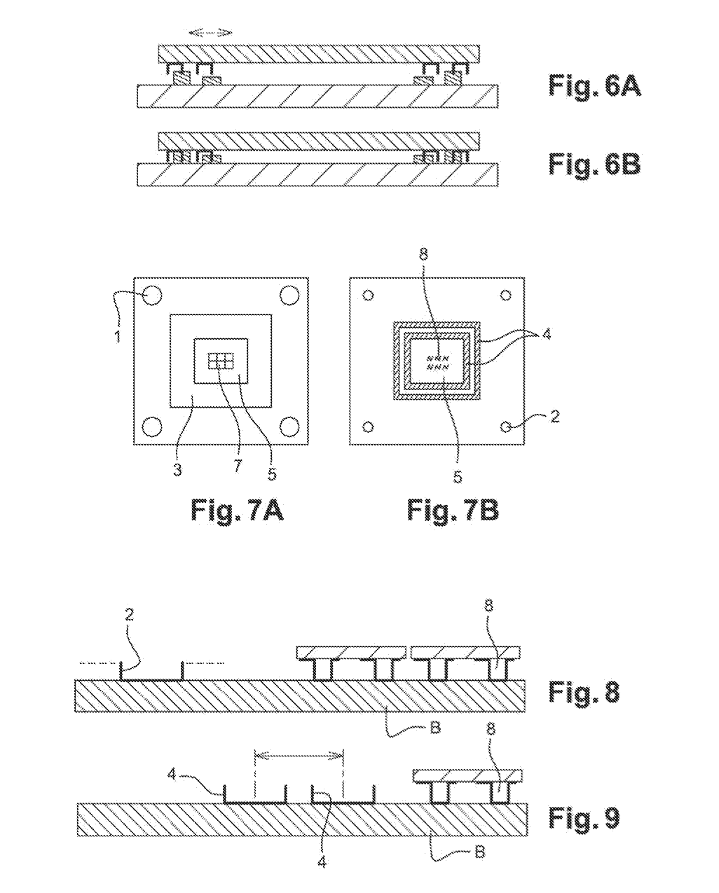

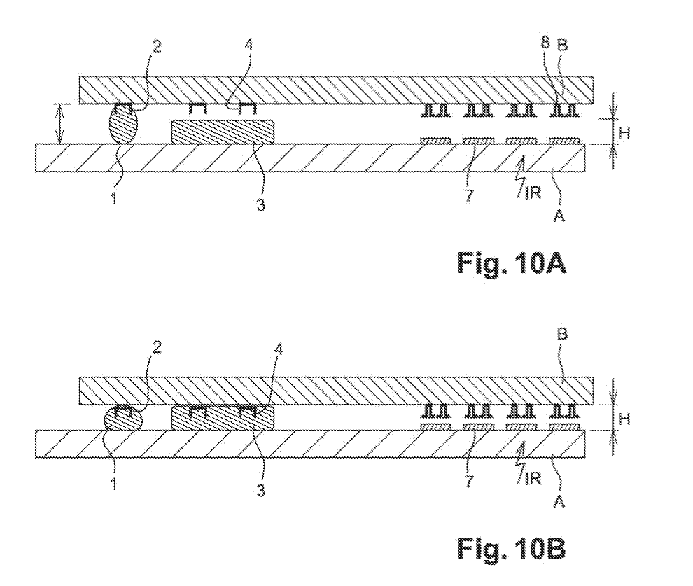

The assembly steps are as detailed above and illustrated in general terms in FIG. 2. FIGS. 00A to 10B illustrate schematically the respective positions of the components A and B at the end of the pre-insertion step (FIG. 10A) and then at the end of the insertion (FIG. 10B).

The following steps can be distinguished. First, putting the surfaces of the components A and B to be assembled opposite each other. Secondly, spatial alignment, in particular of the pre-insertion inserts 2 with the balls 1 and of the double insertion ring 4 with the solder bead 3 Thirdly, the pre-insertion step, advantageously carried out at ambient temperature and with almost zero force. Since the balls are higher than the bead (35 μm as against 20 μm), only the pre-insertion inserts 2 are engaged in the balls 1 (FIG. 10A). Moreover, the insertion step proper so as to engage the double insertion ring 4 in the solder bead 3 (FIG. 10B). In this precise case, it is necessary to physically manipulate the balls 1 until they have a height of around that of the bead 3. In practice, it is therefore necessary to physically manipulate the balls 1 by 15 μm in order to insert the bead insert 4 fully in the solder bead 3. The insertion is advantageously carried out at a pressure of less than 10⁻³ mbar.

### Forces to be Exerted

By way of illustration and in a particular case, the forces to be exerted for the pre-insertion and the insertion have been calculated: raising balls made from AgCuSn; double bead with 4 mm sides; number of balls: 4 or 160. The bead ball geometries are as indicated above.

The following are obtained:

| | Fpi | Fic | Fdbs | Fti = |
|---|---|---|---|---|
| N° of | Pre-insertion | Double bead | Force for | Fic + Fdbs |
| raising | force (in | insertion | deforming the | Total insertion |
| balls | raised shape) | force | raised balls | force |
| 4 | 0.56N | 64N | 3.2N | 67.2N |
| 160 | 22.4N | 64N | 128 | 192N |

If it is wished to have better strength of the lids during transport (after pre-insertion) to an insertion machine, 160 raising (pre-insertion) balls are advantageously placed. This makes it possible to pass from a strength after pre-insertion of 56 g (0.56 N) to a strength of 2.24 kg (22.4 N).

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art

1-13. (canceled)

14. An airtight assembly comprising:
a first component comprising a first support having at its surface at least one spacer arranged at the periphery of said first component, the at least one spacer being composed of a first ductile material, and at least one bead composed of a second ductile material; and
a second component comprising a second support having at its surface at least one insert inserted in the spacer on said first component and at least one bead insert inserted in the at least one bead on said first component to thereby define an airtight central cavity between the first component and the second component;
wherein:
the at least one insert of said second component is composed of a material having a hardness greater than the hardness of the first ductile material and the second ductile material; and
the at least one spacer has a spherical cross section and a height greater than the height of the at least one bead.

15. The airtight assembly of claim 14, wherein at least one of the at least one insert and the at least one bead insert is hollow.

16. The airtight assembly of claim 15, wherein at least one of the at least one insert and the at least one bead insert has a beveled free end.

17. The airtight assembly of claim 14, wherein at least one of the at least one insert and the at least one bead insert is inserted so as to overlap in the spacer and the bead, respectively.

18. The airtight assembly of claim 14, wherein the at least one spacer has a mechanical deformation in its surface in the form of a compression.

19. The airtight assembly of claim 14, wherein the first and the second components are chosen from the group consisting of chips and wafers.

20. The airtight assembly of claim 19, wherein the airtight assembly comprises a chip-to-wafer assembly.

21. The airtight assembly of claim 19, wherein the airtight assembly comprises a wafer-to-wafer assembly.

22. The airtight assembly of claim 14, wherein:
the first component is a lid having a plurality of filters at the airtight central cavity; and
the second component is a bolometer having a plurality of studs at the airtight central cavity.

23. The airtight assembly of claim 14, wherein:
the at least one bead comprises a plurality of beads; and
the at least one bead insert comprises a plurality of bead inserts.

24. A stack of airtight assemblies, each airtight assembly in the stack of airtight assemblies comprising:
a first component comprising a first support having at its surface at least one spacer arranged at the periphery of said first component, the at least one spacer being composed of a first ductile material, and at least one bead composed of a second ductile material; and
a second component comprising a second support having at its surface at least one insert inserted in the at least one spacer and at least one bead insert inserted in the at least one bead to thereby define an airtight central cavity between the first component and the second component;
wherein:
the at least one insert is composed of a material having a hardness greater than the hardness of the first ductile material and the second ductile material; and
the at least one spacer has a spherical cross section with a mechanical deformation in its surface in the form of a compression, and a height greater than the height of the at least one bead.

25. The stack of assemblies of claim 24, further comprising a layer composed of a flexible material arranged between each airtight assembly.

26. The stack of assemblies of claim 24, wherein:
at least one of the at least one insert and the at least one bead insert is hollow; and
at least one of the at least one insert and the at least one bead insert has a beveled free end.

27. The stack of assemblies of claim 24, wherein at least one of the at least one insert and the at least one bead insert is inserted so as to overlap in the at least one spacer and the at least one bead, respectively.

28. The stack of assemblies of claim 24, wherein the first and the second components are chosen from the group consisting of chips and wafers.

29. The stack of assemblies of claim 28, wherein the airtight assembly comprises at least one of a chip-to-wafer assembly and a wafer-to-wafer assembly.

30. The stack of assemblies of claim 24, wherein:
the first component is a lid having a plurality of filters at the airtight central cavity; and
the second component is a bolometer having a plurality of studs at the airtight central cavity.

31. A method of manufacturing an airtight assembly, the method comprising:
providing a first component comprising a first support having at its surface and at least one bead composed of a first ductile material, and at least one spacer arranged at the periphery of said first component, the at least one spacer being composed of a second ductile material, has a spherical cross section with a mechanical deformation in its surface, and has a height greater than the height of the at least one bead;
providing a second component comprising a second support having at its surface at least one insert and at least one bead insert, the at least one insert being composed of a material having a hardness greater than the hardness of the first ductile material and the second ductile material; and
putting the surface of the first component having the at least one spacer and the at least one bead and the surface of the second component having the at least one insert and the at least one bead insert, opposite each other;
aligning at least partially the at least one spacer and the at least one insert, and the at least one bead and the at least one bead insert;
performing a pre-insertion of at least the at least one insert in the at least one spacer; and then
inserting the at least one insert and the at least one bead insert in the at least one spacer and the at least one bead, respectively,
wherein the method is performed at ambient temperature.

32. The method of claim 31, wherein the inserting step is conducted in a controlled atmosphere.

33. A method of manufacturing stack of airtight assemblies, the method comprising:
providing a plurality of first components comprising a first support having at its surface and at least one bead composed of a first ductile material, and at least one spacer arranged at the periphery of said first component, the at least one spacer being composed of a second ductile material, has a spherical cross section with a mechanical deformation in its surface, and has a height greater than the height of the at least one bead;
providing a plurality of second components comprising a second support having at its surface at least one insert and at least one bead insert, the at least one insert being composed of a material having a hardness greater than the hardness of the first ductile material and the second ductile material; and
putting the surface of each first component having the at least one spacer and the at least one bead and the surface of each respective second component having the at least one insert and the at least one bead insert, opposite each other;
aligning at least partially the at least one spacer and the at least one insert, and the at least one bead and the at least one bead insert;
stacking the airtight assemblies;
positioning a layer composed of flexible material between each airtight assembly;
performing a pre-insertion of at least the at least one insert in the at least one spacer; and then
inserting the at least one insert and the at least one bead insert in the at least one spacer and the at least one bead, respectively,
wherein the method is performed at ambient temperature.
